(19) United States
(12) Patent Application Publication
(10) Pub. No.: US 2025/0141430 A1
(43) Pub. Date: May 1, 2025

(54) SYSTEMS AND METHODS FOR ACOUSTIC FILTERS OPERATING AT HIGH FREQUENCIES

(71) Applicant: Avago Technologies International Sales Pte. Limited, Singapore (SG)

(72) Inventors: Andriy Yatsenko, Vaterstetten (DE); Winfried Nessler, München (DE); Stephan Marksteiner, München (DE); Alberto Hueltes, Pentling (DE)

(21) Appl. No.: 18/498,015

(22) Filed: Oct. 30, 2023

(51) Int. Cl. H03H 9/60; H03H 9/13; H03H 9/205

(52) U.S. Cl. CPC H03H 9/605; H03H 9/132; H03H 9/205

(57) ABSTRACT

The subject technology is directed to acoustic filter systems and methods. In an embodiment, the subject technology provides a first resonator, a second resonator, and a third resonator. The first resonator comprises a first layer coupled to and positioned between a first electrode and a second electrode. The second resonator is coupled to the first resonator at a first node. The third resonator is coupled to the first node and a ground terminal. The third resonator comprises a second layer coupled to and positioned between a third electrode and a fourth electrode. Depending on the implementation, each resonator may be associated with one or more thickness extension (TE) modes and the device can function in high-frequency ranges (e.g., greater than 5 GHz) with low insertion loss. There are other embodiments as well.

### FIELD OF INVENTION

The subject technology is directed to acoustic filter systems and operating methods thereof.

### BACKGROUND OF THE INVENTION

Acoustic filters, known for their ability to selectively transmit certain frequency ranges while attenuating others, have been instrumental in various applications ranging from audio systems to advanced communication devices. Over the past decades, acoustic filters have been utilized in numerous systems such as radio frequency (RF) communication devices, mobile phones, and other electronic systems. However, as technological advancements continue and demands for faster data transmission rates and broader bandwidths rise, there is a significant push towards operating at much higher frequencies (e.g., greater than 5 GHz), which are becoming increasingly important for applications in next-generation communication systems, ultra-fast wireless data transmission, and various emerging technologies.

Various approaches for advanced acoustic filter systems have been explored, but they have proven to be insufficient. It is important to recognize the need for new and improved systems and methods for acoustic filters.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1 is a schematic diagram illustrating an acoustic filter according to embodiments of the subject technology.

FIG. 2 is a graph illustrating the frequency responses of an acoustic resonator according to embodiments of the subject technology.

FIGS. 3A-3E are cross-sectional schematic diagrams of resonators of an acoustic filter according to embodiments of the subject technology.

FIGS. 4A-4B are graphs illustrating the frequency responses of an acoustic filter according to embodiments of the subject technology.

FIG. 5 is a schematic diagram illustrating an acoustic filter according to embodiments of the subject technology.

FIG. 6 is a schematic diagram illustrating an acoustic filter according to embodiments of the subject technology.

FIG. 7 is a schematic diagram illustrating an acoustic filter according to embodiments of the subject technology.

### DETAILED DESCRIPTION OF THE INVENTION

The subject technology is directed to acoustic filter systems and methods. In an embodiment, the subject technology provides a first resonator, a second resonator, and a third resonator. The first resonator comprises a first layer coupled to and positioned between a first electrode and a second electrode. The second resonator is coupled to the first resonator at a first node. The third resonator is coupled to the first node and a ground terminal. The third resonator comprises a second layer coupled to and positioned between a third electrode and a fourth electrode. Depending on the implementation, each resonator may be associated with one or more thickness extension (TE) modes and the device can function in high-frequency ranges (e.g., greater than 5 GHz) with low insertion loss. There are other embodiments as well.

Acoustic filters are important components in a wide range of applications, including audio and communication devices, radar systems, medical imaging systems, satellite communication systems, and/or the like. The term “acoustic filter” may refer to a device that can isolate and transmit specific frequency ranges. For instance, an acoustic filter may be designed to selectively attenuate certain frequencies and allow other frequencies to pass through relatively unattenuated. The acoustic filter operates by converting the electrical signal applied to the electrodes into an acoustic wave in the resonator, which may include a layer of piezoelectric material coupled between two conductive plates (e.g., electrodes). Depending on the application, acoustic filters can be designed to operate at a wide range of frequencies, from a few kilohertz to several gigahertz.

As the demand for high-frequency devices continues to grow, it remains a challenging task to design and manufacture acoustic filters that operate at high frequencies (e.g., greater than 7 GHZ). Various approaches for implementing acoustic filters in high-frequency ranges involve operating the resonator at a certain TE mode, under which the resonator may undergo periodic expansions and contractions, leading to an acoustic wave's propagation. The term “thickness extension mode” or “thickness extensional mode” may refer to a type of vibration (e.g., along the thickness direction) that occurs in the resonator when it is excited with an electrical signal. For instance, a resonator may operate at a TE₁ mode in which the resonator exhibits a half-wavelength resonance. However, high-frequency operations usually require ultra-thin piezoelectric (e.g., less than 0.15 μm) and electrode layers (e.g., less than 0.06 μm), which not only leads to increased resistivity and limited resonator areas but also introduces manufacturing complexities and performance limitations, such as increased insertion loss and compromised electrostatic discharge (ESD) robustness.

In various embodiments, the subject technology provides an acoustic filter capable of operating at high-frequency ranges (e.g., greater than 5 GHz). By employing higher-order TE modes (e.g., TE₂, TE₃, etc.), embodiments of the subject technology enable the construction of acoustic filters that balance key performance characteristics without sacrificing manufacturability or operational reliability. Such an approach allows acoustic filters to operate with improved selectivity, reduced insertion loss, and enhanced ESD resilience, satisfying the demands of high-frequency applications in various operational settings.

The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the subject technology is not intended to be limited to the embodiments presented but is to be accorded the widest scope consistent with the principles and novel features disclosed herein.

In the following detailed description, numerous specific details are set forth in order to provide a more thorough understanding of the subject technology. However, it will be apparent to one skilled in the art that the subject technology may be practiced without necessarily being limited to these specific details. In other instances, well-known structures and devices are shown in block diagram form, rather than in detail, in order to avoid obscuring the subject technology.

The reader's attention is directed to all papers and documents which are filed concurrently with this specification and which are open to public inspection with this specification and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

When an element is referred to herein as being “disposed” in some manner relative to another element (e.g., disposed on, disposed between, disposed under, disposed adjacent to, or disposed in some other relative manner), it is to be understood that the elements can be directly disposed relative to the other element (e.g., disposed directly on another element), or have intervening elements present between the elements. In contrast, when an element is referred to as being “disposed directly” relative to another element, it should be understood that no intervening elements are present in the “direct” example. However, the existence of a direct disposition does not exclude other examples in which intervening elements may be present.

Similarly, when an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements. However, the existence of direct bonding does not exclude other forms of bonding, in which intervening elements may be present.

Likewise, when an element is referred to herein as being a “layer,” it is to be understood that the layer can be a single layer or include multiple layers. For example, a conductive layer may comprise multiple different conductive materials or multiple layers of different conductive materials, and a dielectric layer may comprise multiple dielectric materials or multiple layers of dielectric materials. When a layer is described as being coupled or connected to another layer, it is to be understood that the coupled or connected layers may include intervening elements present between the coupled or connected layers. In contrast, when a layer is referred to as being “directly” connected or coupled to another layer, it should be understood that no intervening elements are present between the layers. However, the existence of directly coupled or connected layers does not exclude other connections in which intervening elements may be present.

Moreover, the terms left, right, front, back, top, bottom, forward, reverse, clockwise and counterclockwise are used for purposes of explanation only and are not limited to any fixed direction or orientation. Rather, they are used merely to indicate relative locations and/or directions between various parts of an object and/or components.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” In this application, the use of the singular includes the plural unless specifically stated otherwise, and use of the terms “and” and “or” means “and/or” unless otherwise indicated. Moreover, the use of the terms “including” and “having,” as well as other forms, such as “includes,” “included,” “has,” “have,” and “had,” should be considered non-exclusive. Also, terms such as “element” or “component” encompass both elements and components comprising one unit and elements and components that comprise more than one unit, unless specifically stated otherwise.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items. By way of example, the phrases “at least one of A, B, and C” or “at least one of A, B, or C” each refer to only A, only B, or only C; and/or any combination of A, B, and C. In instances where it is intended that a selection be of “at least one of each of A, B, and C,” or alternatively, “at least one of A, at least one of B, and at least one of C,” it is expressly described as such.

One general aspect includes a device, which comprises a first resonator. The first resonator comprises a first layer coupled to and positioned between a first electrode and a second electrode. The first layer comprises a first piezoelectric material. The first resonator is associated with a first thickness extension (TE) mode, the first TE mode comprises a TEₙ mode, wherein n is an integer greater than or equal to 2. The device further comprises a second resonator coupled to the first resonator at a first node. The device further comprises a third resonator coupled to the first node and a first ground terminal. The third resonator comprises a second layer coupled to and positioned between a third electrode and a fourth electrode. The second layer comprises a second piezoelectric material. The second resonator further comprises a third layer coupled to the third electrode.

Implementations may include one or more of the following features. The first TE mode is associated with a frequency of at least 6 GHz. The third layer comprises a mass load. The device further comprises a filter coupled to the first resonator, the filter being configured to suppress a TE₁ frequency. The first electrode and the second electrode are characterized by a thickness difference of at least 30%. The third electrode and the fourth electrode are characterized by a thickness difference of at least 30%. The third electrode and the fourth electrode are characterized by a thickness difference of less than 10%. The first electrode and the second electrode are characterized by a thickness difference of at least 150%, the first TE mode comprising a TE₂ mode. The device further comprises a fourth resonator coupled to the second resonator and a second ground terminal. The first resonator and the second resonator are associated with the first TE mode. The third resonator and the fourth resonator are associated with a second TE mode. The second TE mode may be different from the first TE mode. The second TE mode comprises a TE₁ mode. The device further comprises a filter coupled to the first resonator, the filter being configured to suppress a TE₁ frequency. The filter comprises an inductor and a capacitor.

According to another embodiment, the subject technology provides a device, which comprises a first resonator comprising a first layer coupled to and positioned between a first electrode and a second electrode. The first layer comprises a first piezoelectric material. The first resonator is associated with a first thickness extension (TE) mode. The device further comprises a second resonator coupled to the first resonator at a first node, the second resonator being associated with the first TE mode. The device further comprises a third resonator coupled to the first node and a first ground terminal, the third resonator being associated with a second TE mode. The device further comprises a first filter coupled to the first resonator.

Implementations may include one or more of the following features. The first resonator and the third resonator are configured in parallel. The device further comprises a second filter coupled to the second resonator. The first filter is configured to suppress a third TE mode associated with the first resonator.

According to yet another embodiment, the subject technology provides a device, which comprises a first resonator comprising a first layer coupled to and positioned between a first electrode and a second electrode. The first layer comprises a first piezoelectric material. The first resonator is associated with a first thickness extension (TE) mode, the first TE mode being associated with a frequency of at least 5 GHz. The device further comprises a second resonator coupled to the first resonator at a first node, the second resonator being associated with the first TE mode. The device further comprises a third resonator coupled to the first node and a first ground terminal. The device further comprises a fourth resonator coupled to the second resonator and a second ground terminal.

Implementations may include one or more of the following features. The first resonator and the second resonator are configured in series. The third resonator and the fourth resonator are associated with a second TE mode, the second TE mode being different from the first TE mode.

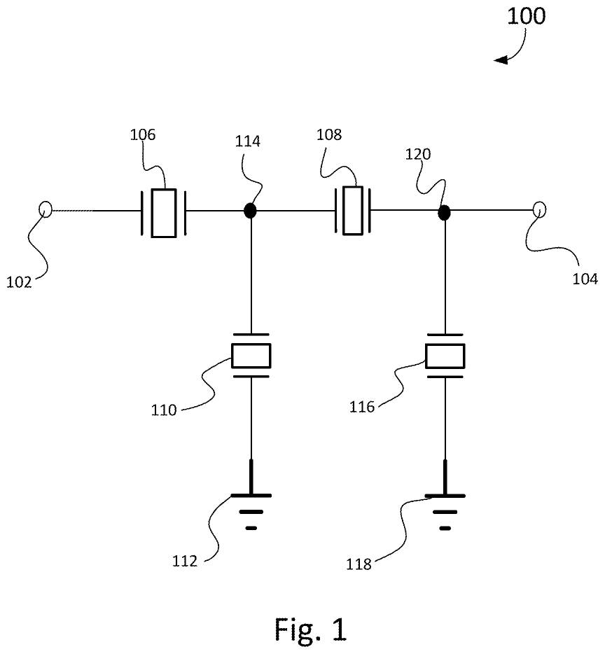

FIG. 1 is a schematic diagram illustrating an acoustic filter 100 according to embodiments of the subject technology. This diagram merely provides an example, which should not unduly limit the scope of the claims. One of ordinary skill in the art would recognize many variations, alternatives, and modifications. Depending on the application, acoustic filter 100 may be implemented as a bulk acoustic wave (BAW), a film bulk acoustic resonator (FBAR), and/or the like.

As an example, acoustic filter 100 includes a first port 102 and a second port 104, which may be configured to receive input or output signals (e.g., radio frequency signals). The ports can be adapted for various applications such as signal transmission or reception in communication devices. For instance, first port 102 may be a transmit port and second port 104 may be an antenna port. In an example, first port 102 may be a receive port and second port 104 may be an antenna port. For instance, acoustic filter 100 includes a resonator 106 (e.g., a first resonator recited in claim 1). The term “resonator” may refer to an electronic component that exhibits resonance or resonant behavior when subject to a certain frequency. Resonators may be used to generate and filter acoustic waves and may include, without limitation, a piezoelectric crystal resonator, a metal resonator, a polymer resonator, and/or the like.

In various implementations, resonator 106 may be associated with or operate at a first thickness extension (TE) mode. For example, the term “thickness extension mode” or “thickness extensional mode” may refer to a type of vibration (e.g., along the thickness direction) that occurs in the resonator when it is excited with an electrical signal. As an example, a TE mode is characterized by the number of nodes—the points where the displacement field is zero—across the thickness of the resonator. For example, TE₁ mode is the lowest-order TE mode and is characterized by one node in the strain field across the thickness of the resonator. In TE₁ mode, the resonator exhibits a half-wavelength resonance. In some cases, the TE₁ mode—which may be referred to as the main mode—defines the basic operational frequency of the resonator, with the vibration resulting in a significant displacement of material at the resonator's top and bottom surfaces while the center (e.g., a center of gravity point along the thickness) remains relatively stationary.

In various examples, the TE₂ mode is second order or next-higher-order (relative to TE₁) TE mode. The TE₂ mode is characterized by two nodes in the strain field across the thickness of the resonator. For example, operating in TE₂ mode, the resonator exhibits a full-wavelength resonance, with a full wavelength fitting between the top and bottom surfaces of the resonator. The TE₂ mode may occur at a frequency higher than that of the TE₁ mode. The TE₃ mode is characterized by three nodes in the strain field across the thickness of the resonator. It divides the resonator into three segments, each exhibiting a half-wavelength resonance. For example, TE₃ mode would occur at a frequency higher than that of the TE₁ mode and TE₂ mode. As complexity of the vibration pattern increases, it leads to intricate waveforms and multiple nodes of minimum vibration within the resonator's thickness. The selection of the TE mode in which a resonator operates may directly influence the acoustic filter's performance and suitability for various applications. Each resonator may be configured to utilize one or more TE modes (e.g., TE₁, TE₂, TE₃, etc.) for frequency filtering. Depending on the implementation, the first utilized TE mode may be greater than TE₁ (e.g., TE₂, TE₃, etc.), enabling acoustic filter 100 to achieve high resonant frequencies (e.g., at least 5 GHz), reduced insertion loss, increased bandwidth, and enhanced selectivity. In some examples, the first TE mode is associated with a frequency of at least 6 GHz.

In some embodiments, a resonator 108 (e.g., a second resonator recited in claim 1) may be coupled to resonator 106 at a node 114 (e.g., a first node recited in claim 1). For instance, the term “node” may refer to a point that is used to couple two or more elements (e.g., resonators, resistors, ground terminal, etc.). The two or more resonators may be coupled together either directly or via a coupling component. For example, resonator 108 may be associated with the first TE mode. In other words, resonator 106 and resonator 108 may be associated with or operate at the same TE mode (e.g., the first TE mode). In some examples, acoustic filter 100 further includes resonator 110 (e.g., third resonator recited in claim 1) coupled to node 114 and ground terminal 112 (e.g., first ground terminal recited in claim 1). The term “ground terminal” or “ground” may refer to a point of reference in an electrical circuit where the voltage is considered to be zero. Resonator 110 may be associated with or operate at a second TE mode (e.g., TE₁, TE₂, TE₃, etc.). Depending on the implementation, the first TE mode and the second TE mode may be the same or different.

According to some embodiments, acoustic filter 100 further includes resonator 116 (e.g., fourth resonator recited in claim 9) coupled to resonator 108 and a ground terminal 118 (e.g., second ground terminal recited in claim 9). For example, resonator 116 may be coupled to resonator 108 through node 120. In various implementations, acoustic filter 100 may be configured in a ladder topology, where multiple resonators are connected in a series-shunt configuration to achieve desired filter characteristics. For example, resonator 106 and resonator 108 may be configured in series and may be referred to as “series resonator(s).” Resonator 110 and resonator 116 may be configured in parallel and may be referred to as “shunt resonator(s).” In various implementations, resonator 106 and resonator 108 may be associated with or operate at the first TE mode (e.g., TE₁). Resonator 110 and resonator 116 may be associated with or operate at the second TE mode. Depending on the implementation, the first TE mode and the second TE mode may be the same or different.

Depending on the application, the number and configuration of series and shunt resonators may be adjusted to achieve the desired operating frequency and filter characteristics. Furthermore, the resonant frequency of a resonator may be determined by its physical properties, such as its size, shape, and material composition. In some cases, achieving higher frequencies often necessitates the reduction of resonator size, which may introduce manufacturing complexities due to the precision required in fabricating and aligning these smaller components. Therefore, the material characteristics and design configurations of the resonators may be optimized for achieving desired frequency responses while maintaining operation efficiency and cost-effectiveness.

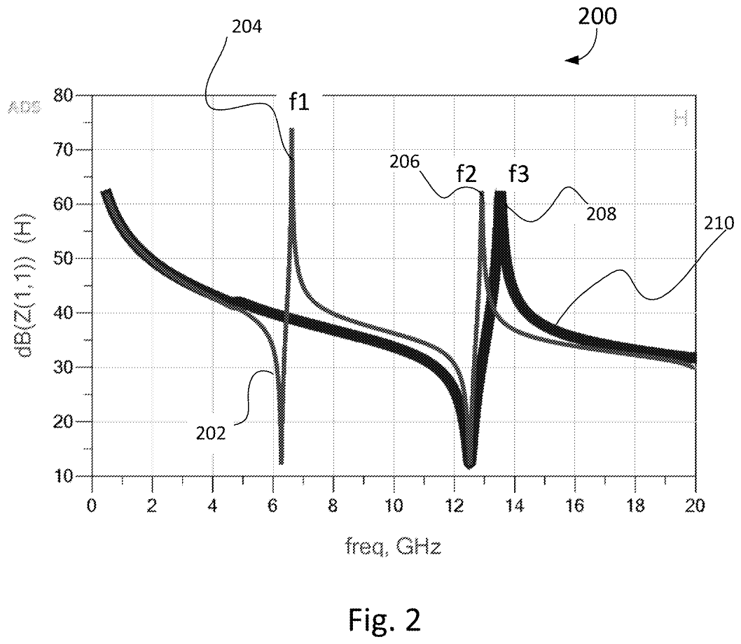

FIG. 2 provides graph 200 illustrating the frequency responses of an acoustic resonator according to embodiments of the subject technology. This diagram merely provides an example, which should not unduly limit the scope of the claims. One of ordinary skill in the art would recognize many variations, alternatives, and modifications. As an example, FIG. 2 illustrates the frequency responses of an acoustic resonator (e.g., acoustic filter 100 of FIG. 1) operating in a high-frequency range (e.g., from 12 to 14 GHz).

Depending on the implementation, the acoustic resonator may operate at various TE modes. For example, curve 202 illustrates the frequency response of the acoustic resonator operating at TE₂ mode. As shown, curve 202 includes a first peak 204 at resonant frequency f1 (e.g., greater than 6 GHZ) and a second peak 206 at resonant frequency f2 (e.g., greater than 12 GHz). In some examples, curve 210 illustrates the frequency response of the acoustic resonator operating at TE₁ mode. Curve 210 may include a third peak 208 at resonant frequency f3 (e.g., greater than 13 GHZ). In high-frequency applications (e.g., greater than 5 GHz), operating the acoustic filter in TE₂, TE₃ and higher modes offer several benefits over TE₁ mode, including reduced ohmic loss, lower acoustic coupling, a robust main mode, and reduced manufacturing complexity. This results in acoustic filters with improved ESD performance, power handling, and overall performance.

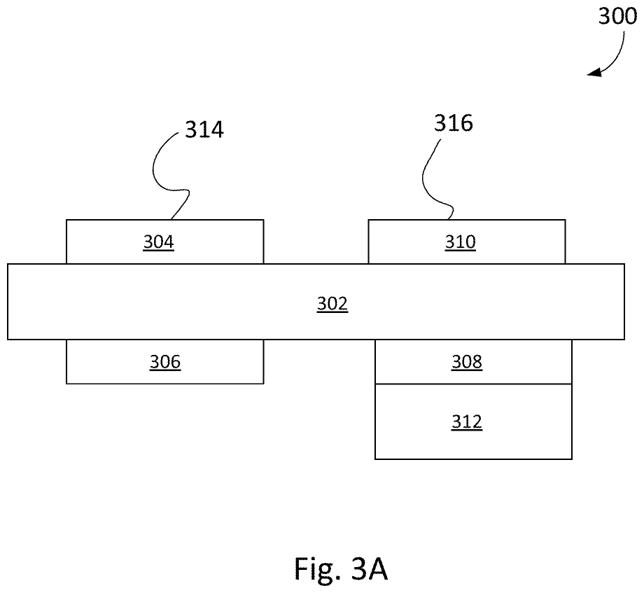

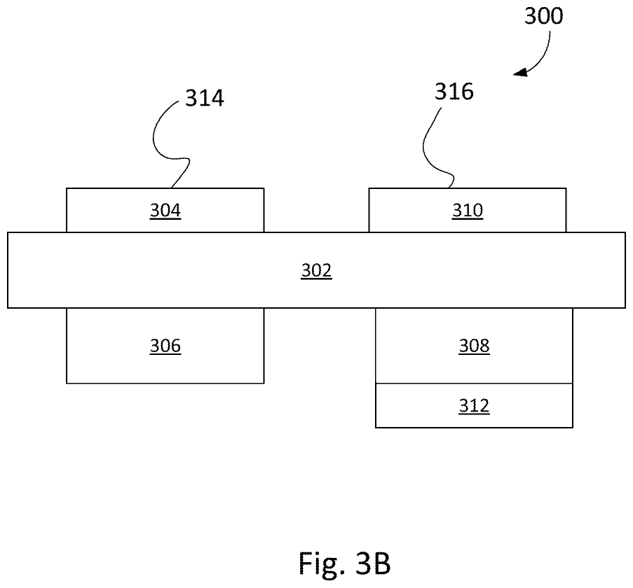

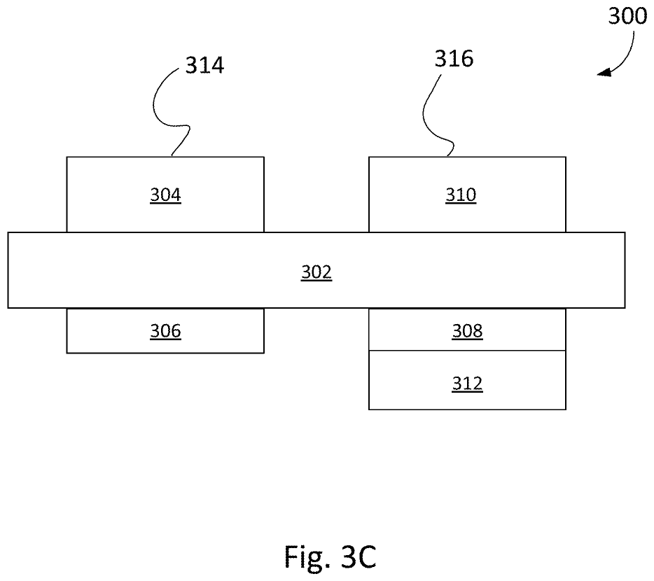

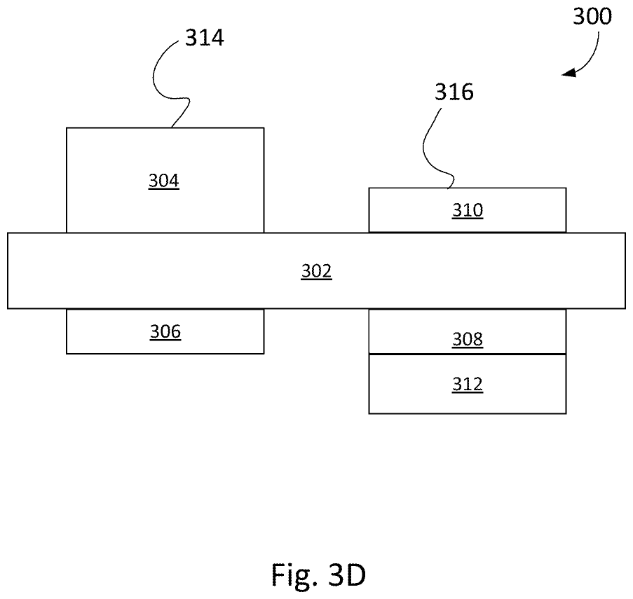

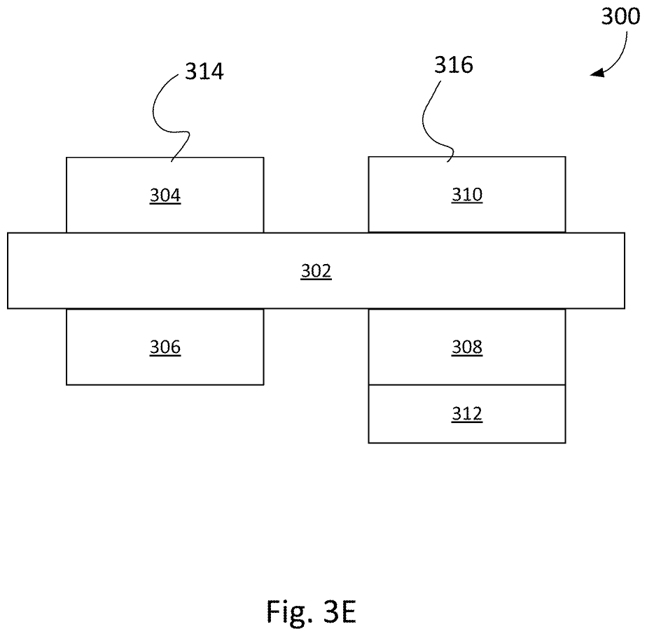

FIGS. 3A-3E are cross-sectional schematic diagrams of resonators of an acoustic filter 300 according to embodiments of the subject technology. This diagram merely provides an example, which should not unduly limit the scope of the claims. One of ordinary skill in the art would recognize many variations, alternatives, and modifications. In various implementations, the resonators of acoustic filter 300 may be implemented as one of the resonators of an acoustic filter (e.g., acoustic filter 100 of FIG. 1).

As shown in FIG. 3A, acoustic filter 300 includes resonator 314 (e.g., a first resonator recited in claim 1), which may include layer 302 coupled to and/or positioned between a first electrode 304 and a second electrode 306. Layer 302 may include a first piezoelectric material. The term “piezoelectric material” may refer to a material that generates an electric charge when subjected to mechanical stress or undergoes mechanical deformation when subjected to an electric field. The piezoelectric material may include, without limitation, quartz, lead zirconate titanate (PZT), lithium niobate (LiNbO₃), aluminum nitride (AlN), aluminium scandium nitride (ASN), scandium nitride (ScN), zinc oxide (ZnO), lithium tantalite (LiTaO₃), Polyvinylidene fluoride (PVDF), and/or the like. Depending on the implementation, layer 302 may be configured in a multi-layer structure or a single-layer structure. For example, term “electrode” may refer to a conductor that is used to establish electrical contact with a non-metallic part of a circuit. Electrodes may be used to apply an electric field to a piezoelectric material (e.g., layer 302), which can cause the piezoelectric material to deform and generate an acoustic wave. The electrodes may be made from a variety of materials including, without limitation, molybdenum, tungsten, aluminum, ruthenium, gold, silver, platinum, copper, conductive polymers, and/or the like. Depending on the implementation, the electrodes may be configured in a multi-layer structure or a single-layer structure.

In some embodiments, acoustic filter 300 further includes resonator 316 (e.g., third resonator recited in claim 1), which may include layer 302 coupled to and/or positioned between a third electrode 308 and a second electrode 306. Layer 302 may include a second piezoelectric material. The first piezoelectric material and the second piezoelectric material may be the same or different. Depending on the implementation, resonator 314 and resonator 316 may share a same piezoelectric layer (e.g., layer 302) or have separate piezoelectric layers. In various examples, resonator 316 includes layer 312 (e.g., third layer recited in claim 1) coupled to third electrode 308. For example, layer 312 includes a mass load. For example, term “mass loads” or “mass load” may refer to materials that are added to a resonator in order to change its resonant frequency. Mass loads may be used to tune the resonator to a specific frequency, in order to create multiple resonant frequencies needed for the filter. The mass loads may include, without limitation, metallic dots, polymer materials, dielectric materials, and/or the like. Depending on the implementation, layer 312 may have a thickness greater than or less than or equal to that of third electrode 308.

In various implementations, the resonant frequency of a resonator (e.g., resonators 314, 316) may be associated with the thickness of the individual layers (e.g., electrode, piezoelectric layer, mass loads, and/or the like). For high-frequency applications, increasing the thickness of the electrodes and/or piezoelectric layers may enable the use of higher TE modes. This offers several advantages, including reduced electrode resistivity, increased resonator area, and enhanced RF performance, resulting in a more reliable and efficient frequency response tailored for demanding applications. The resonator may be configured in a symmetrical or asymmetrical structure depending on the application. For instance, FIG. 3A illustrates a symmetrical structure for resonators 314 and 316. In resonator 314, a thickness of first electrode 304 may be substantially the same as that of second electrode 306. In resonator 316, a thickness of third electrode 308 may be substantially the same as that of fourth electrode 310. It is to be appreciated that a thickness difference of less than 10% may be considered as substantially the same for the purpose of this disclosure. Depending on the implementation, first electrode 304 may have a thickness greater than or less than or equal to that of second electrode 306. In resonator 316, third electrode 308 and fourth electrode 310 may be characterized by a thickness difference of less than 10%. Depending on the implementation, third electrode 308 may have a thickness greater than or less than or equal to that of fourth electrode 310. In some cases, layer 312 may have a thickness greater than that of third electrode 308.

In some embodiments, resonator 314 may be associated with or operate at a first TE mode; resonator 316 may be associated with or operate at a second TE mode. For instance, resonator 314 may be a series resonator in acoustic filter 300; resonator 316 may be a shunt resonator in acoustic filter 300. The first TE mode may comprise a TEₙ mode, wherein n is an integer greater than or equal to 2. In other words, the first TE mode may be TE₂ mode or higher. In an example, resonator 314 may operate at TE₂ mode, which is associated with a frequency of at least 6 GHz. For example, a 12 GHz operating frequency is used for various communication related application, and other operating frequencies may be possible as well, depending on the implementation. In some cases, resonator 316 may be associated with or operate at a TEₙ mode, wherein n is an integer greater than or equal to 2. In other words, the second TE mode may be TE₂ mode or higher. In some examples, resonator 316 may operate at TE₂ mode, which is associated with a frequency of at least 6 GHz. Depending on the application, the first TE mode and the second TE mode may be the same or different. For instance, the first TE mode and the second TE mode may both be TE₁ mode.

As shown in FIG. 3B, second electrode 306 may have a thickness greater than that of first electrode 304. For instance, first electrode 304 and second electrode 306 may be characterized by a thickness difference of at least 30%. For example, the thickness difference may be related to acoustic impedance and/or electrical conductance of electrode materials. In some examples, first electrode 304 and second electrode 306 may be characterized by a thickness difference of at least 150%. In various embodiments, third electrode 308 may have a thickness greater than that of fourth electrode 310. For instance, third electrode 308 and fourth electrode 310 may be characterized by a thickness difference of at least 30%. In some examples, third electrode 308 and fourth electrode 310 may be characterized by a thickness difference of at least 150%. It is to be appreciated that the thickness differences between electrodes may result in asymmetrical configurations that allow the resonators (e.g., resonators 314, 316) to operate at higher TE modes. Such configurations are well-suited to meet the demands of high-frequency applications, including 5G communication, automotive radar, medical imaging, and/or the like. For instance, resonator 314 and resonator 316 may operate at TE₂ mode or higher. Depending on the application, the first TE mode and the second TE mode may be the same or different. For instance, the first TE mode and the second TE mode may both be TE₂ mode. In some cases, layer 312 may be coupled to third electrode 308. Third electrode 308 may have a thickness greater than that of layer 312.

As shown in FIG. 3C, first electrode 304 may have a thickness greater than that of second electrode 306. For instance, first electrode 304 and second electrode 306 may be characterized by a thickness difference of at least 30%. In some examples, first electrode 304 and second electrode 306 may be characterized by a thickness difference of at least 150%. In various embodiments, fourth electrode 310 may have a thickness greater than that of third electrode 308. For instance, third electrode 308 and fourth electrode 310 may be characterized by a thickness difference of at least 30%. In some examples, third electrode 308 and fourth electrode 310 may be characterized by a thickness difference of at least 150%. In various examples, resonator 314 and resonator 316 may operate at TE₂ mode or higher. Depending on the application, the first TE mode and the second TE mode may be the same or different. For instance, the first TE mode and the second TE mode may both be TE₂ mode. In some cases, layer 312 may be coupled to third electrode 308. Layer 312 may have a thickness greater than that of third electrode 308.

In various embodiments, resonator 314 and resonator 316 may have different configurations. As shown in FIG. 3D, resonator 314 may be configured in an asymmetrical structure and resonator 316 may be configured in a symmetrical structure. For instance, first resonator 304 may have a thickness greater than that of second electrode 306. For instance, first electrode 304 and second electrode 306 may be characterized by a thickness difference of at least 30%. In some examples, first electrode 304 and second electrode 306 may be characterized by a thickness difference of at least 150%. In resonator 316, a thickness of third electrode 308 may be substantially the same as that of fourth electrode 310. In various examples, resonator 314 and resonator 316 may operate at TE₂ mode or higher. In some cases, layer 312 may be coupled to third electrode 308. Layer 312 may have a thickness greater than that of third electrode 308. Depending on the implementation, resonator 314 and resonator 316 may operate at different TE modes. In some examples, the first TE mode and the second TE mode may be associated with a WiFi6 or WiFi7 filter response. For instance, resonator 314 may operate at TE₂ mode or higher. Resonator 316 may operate at TE₁ mode. By operating one or more resonators (e.g., resonators 314, 316) at different TE modes, acoustic filter 300 can address a broader range of frequencies, effectively catering to various application requirements.

In various implementations, as shown in FIG. 3E, to facilitate operations at higher TE modes, the thickness of one or more electrodes (e.g., first electrode 304, second electrode 306, third electrode 308, fourth electrode 310) may be increased. Such enhanced thickness serves to accommodate the specific mechanical and acoustic characteristics required for the operation of resonators at higher TE modes. In some examples, resonator 314 and resonator 316 may operate at TE₃ mode or higher. In some cases, layer 312 may be coupled to third electrode 308. Layer 312 may have a thickness less than that of third electrode 308.

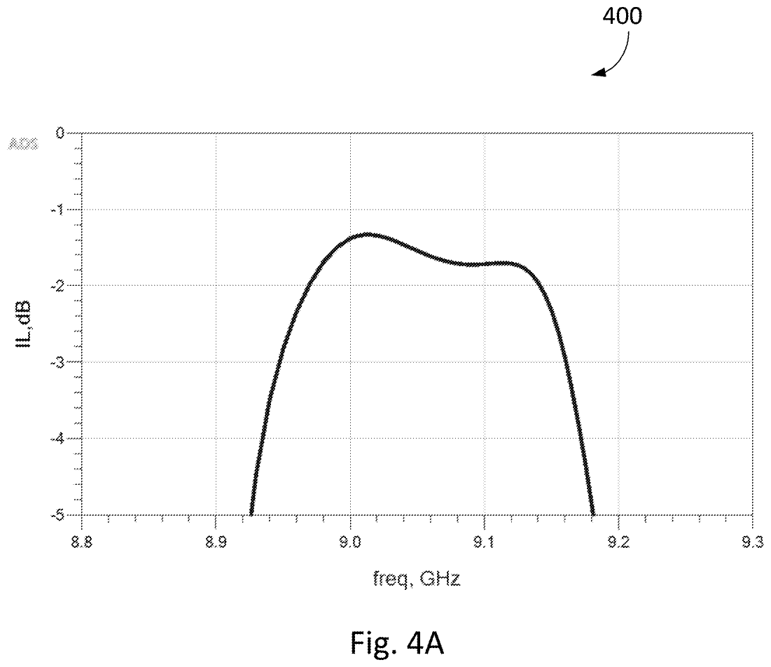

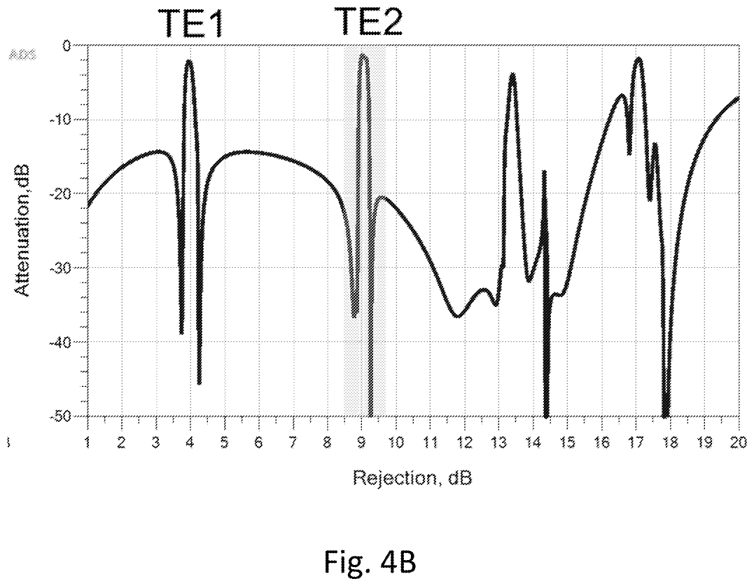

FIGS. 4A-4B are graphs illustrating the frequency responses of an acoustic filter 400 according to embodiments of the subject technology. This diagram merely provides an example, which should not unduly limit the scope of the claims. One of ordinary skill in the art would recognize many variations, alternatives, and modifications. Acoustic filter 400 may be implemented as various types of filters, such as ladder filters, sawtooth filters, bulk acoustic wave filters, butterworth filters, elliptic filters, and/or the like. For instance, acoustic filter 400 may be implemented as a ladder filter (e.g., acoustic filter 100 of FIG. 1).

Depending on the application, acoustic filter 400 may be optimized for operating in a high-frequency band (e.g., greater than 5 GHz). As shown in FIG. 4A, acoustic filter 400 exhibits a low insertion loss (e.g., less than 1.5 dB) throughout its passband (e.g., 9-9.15 GHz). The term “insertion loss” may refer to the amount of signal power that is lost or attenuated when a device or a system is inserted into a transmission line. Insertion loss may be expressed in decibels (dB) and calculated by comparing the power of the input signal to the power of the output signal after the filter. A low insertion loss (e.g., less than 1.5 dB) indicates that the acoustic filter 400 exhibits minimal attenuation, ensuring that signals within the defined passband are transmitted with minimal reduction in amplitude, thereby maintaining the integrity of the signal and ensuring high efficiency.

In various implementations, one or more resonators (e.g., a series resonator or a shunt resonator) may operate at a TE mode greater than TE₁ (e.g., TE₂ or higher). TE₂ mode and higher TE modes have higher resonant frequencies than the TE₁ mode, enabling acoustic filter 400 to operate at higher frequencies. As shown in FIG. 4B, when operating at TE₁ mode, acoustic filter 400 achieves a frequency of around 4 GHz. In contrast, when operating at TE₂ mode, acoustic filter 400 can achieve a frequency of around 9 GHz. The transition to a higher TE mode, compared to TE₁ main mode, permits the use of thicker electrodes and piezoelectric materials. For instance, the resonator may be characterized by a thickness of greater than two micrometers. The increased thicknesses contribute to a more robust structure, thereby minimizing the potential for manufacturing defects and enhancing operational reliability. By operating at a higher TE mode, acoustic filter 400 demonstrates enhanced signal quality, reduced insertion loss, and augmented resilience to environmental and operational stresses.

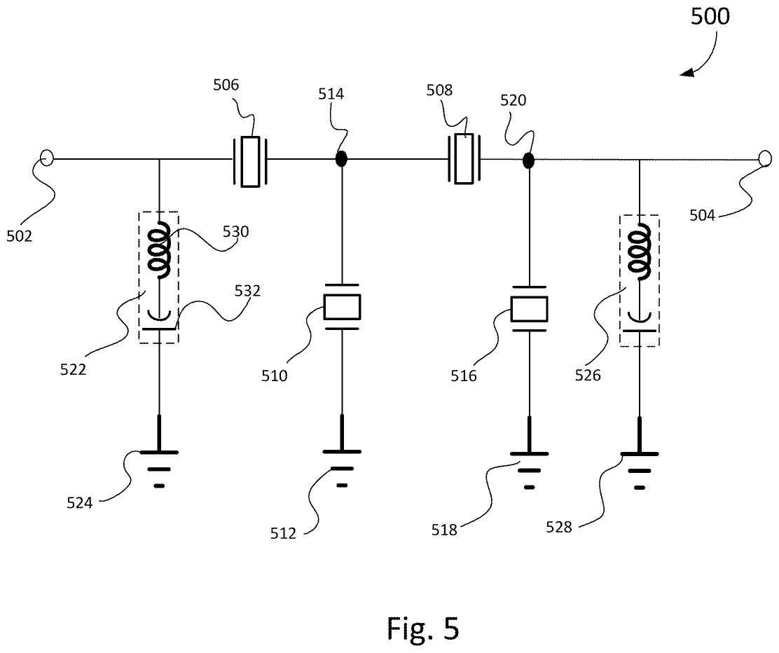

FIG. 5 is a schematic diagram illustrating an acoustic filter 500 according to embodiments of the subject technology. This diagram merely provides an example, which should not unduly limit the scope of the claims. One of ordinary skill in the art would recognize many variations, alternatives, and modifications. Depending on the application, acoustic filter 500 may be implemented as a bulk acoustic wave (BAW), a film bulk acoustic resonator (FBAR), a filter, and/or the like.

As an example, acoustic filter 500 includes a first port 502 and a second port 504, which may be configured to receive input or output signals (e.g., radio frequency signals). The ports can be adapted for various applications such as signal transmission or reception in communication devices. Acoustic filter 500 may include one or more resonators. For instance, acoustic filter 500 includes at least one of resonator 506, resonator 508, resonator 510, and resonator 516. Resonator 506 may be associated with or operate at a first TE mode. The first TE mode may be greater than TE₁. Resonator 508 may be coupled to resonator 506 at node 514. Resonator 508 may be associated with the first TE mode. In other words, resonator 506 and resonator 508 may be associated with or operate at the same TE mode (e.g., first TE mode). In some embodiments, resonator 506 and resonator 508 may be configured in series.

In various implementations, resonator 510 may be coupled to node 514 and a ground terminal 512. Resonator 510 may be associated with or operate at second TE mode (e.g., TE₁, TE₂, TE₃, etc.). Depending on the implementation, the first TE mode and the second TE mode may be the same or different. According to some embodiments, acoustic filter 500 further includes resonator 516 coupled to resonator 508 and ground terminal 518. For instance, resonator 516 may be coupled to resonator 508 through node 520. In some embodiments, resonator 510 and resonator 516 may be configured in parallel. Resonator 516 may be associated with the second TE mode. In other words, resonator 510 and resonator 516 may be associated with or operate at the same TE mode (e.g., the second TE mode).

In various embodiments, one or more resonators of acoustic filter 500 may operate at a high TE mode (e.g., TE₂ or higher). However, one of the challenges of operating acoustic filters at high TE modes is the presence of lower-order TE modes (e.g., TE₁ mode), which may compromise the filter's performance by introducing undesirable signal interference and distortion. In various implementations, acoustic filter 500 may further include a filter 522 configured to suppress and/or remove TE₁ mode frequency. For example, filter 522 may be coupled to resonator 506 and ground terminal 524. Filter 522 may include an LC circuit, which may include an inductor 530 and a capacitor 532. Depending on the implementation, inductor 530 and capacitor 532 may be configured in series or parallel. The term “inductor” may refer to an electrical component that stores energy in a magnetic field when electric current flows through it. The inductor may include, but is not limited to, a coil, a ceramic inductor, a chip inductor, and/or the like. The term “capacitor” may refer to an electronic component that stores energy in an electric field. The capacitor may include, but is not limited to, a ceramic capacitor, a film capacitor, an electrolytic capacitor, and/or the like. The LC circuit can create resonance at a specific frequency, thereby isolating or attenuating unwanted signals at a particular frequency (e.g., the TE₁ frequency). By strategically introducing an LC resonance at the frequency of the main mode (e.g., TE₁ mode), the unwanted mode can be significantly rejected. In some cases, acoustic filter 500 may further include filter 526 coupled to resonator 508 and ground terminal 528.

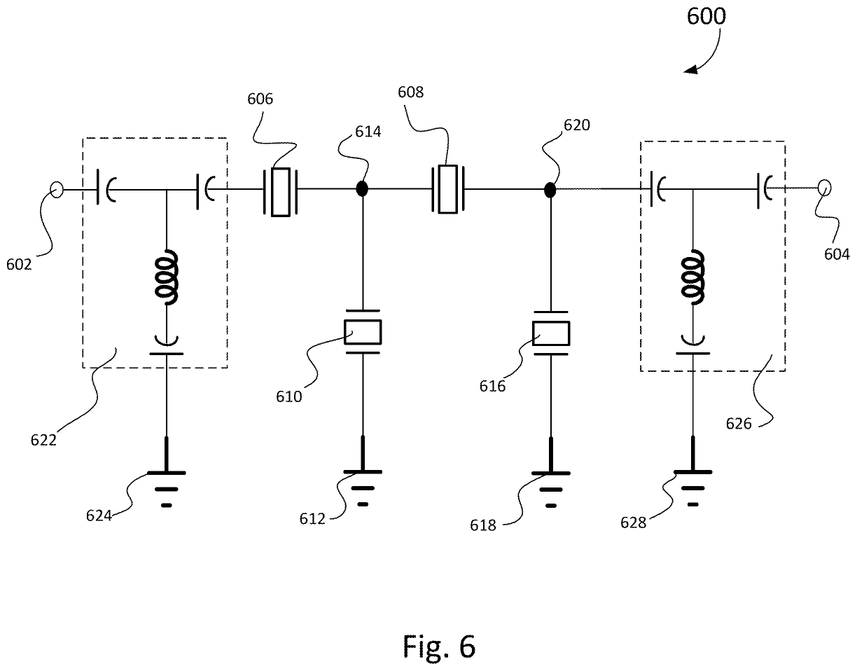

FIG. 6 is a schematic diagram illustrating an acoustic filter 600 according to embodiments of the subject technology. This diagram merely provides an example, which should not unduly limit the scope of the claims. One of ordinary skill in the art would recognize many variations, alternatives, and modifications. Acoustic filter 600 may include at least one of a first port 602, a second port 604, a resonator 606, a resonator 608, a resonator 610, and a resonator 616. Resonator 606 may be associated with or operate at a first TE mode. The first TE mode may be greater than TE₁. Resonator 608 may be coupled to resonator 606 at a node 614. Resonator 608 may be associated with the first TE mode. In other words, resonator 606 and resonator 608 may be associated with or operate at the same TE mode (e.g., the first TE mode). In some embodiments, resonator 606 and resonator 608 may be configured in series.

In various implementations, resonator 610 may be coupled to node 614 and a ground terminal 612. Resonator 610 may be associated with or operate at a second TE mode (e.g., TE₁, TE₂, TE₃, etc.). Depending on the implementation, the first TE mode and the second TE mode may be the same or different. According to some embodiments, acoustic filter 600 further includes resonator 616 coupled to resonator 608 and a ground terminal 618. For instance, resonator 616 may be coupled to resonator 608 through a node 620. In some embodiments, resonator 610 and resonator 616 may be configured in parallel. Resonator 616 may be associated with the second TE mode. In other words, resonator 610 and resonator 616 may be associated with or operate at the same TE mode (e.g., the second TE mode).

In various embodiments, one or more resonators of acoustic filter 600 may operate at a high TE mode (e.g., TE₂ or higher). However, one of the challenges of operating acoustic filters at high TE modes is the presence of lower-order TE modes (e.g., TE₁ mode, which may compromise the filter's performance by introducing undesirable signal interference and distortion. In various implementations, acoustic filter 600 may further include filter 622 configured to suppress TE₁ mode and remove TE₁ frequency. For example, filter 622 may be coupled to resonator 606 and ground terminal 624. Filter 522 may include a high pass circuit. The term “high pass circuit” may refer to a circuit that passes signals with a frequency higher than a certain cutoff frequency and attenuates signals with frequencies lower than the cutoff frequency. The high pass circuit may block the TE₁ mode signal from passing through the filter, thereby effectively suppressing the TE₁ mode during operation. Depending on the implementation, filter 522 may include one or more components including, without limitation, a resistor, a capacitor, an inductor, and/or the like. The one or more components of filter 522 may be configured in series or parallel depending on the frequency of the TE₁ mode and the desired performance of the filter. In some cases, acoustic filter 600 may further include filter 626 coupled to resonator 608 and ground terminal 628.

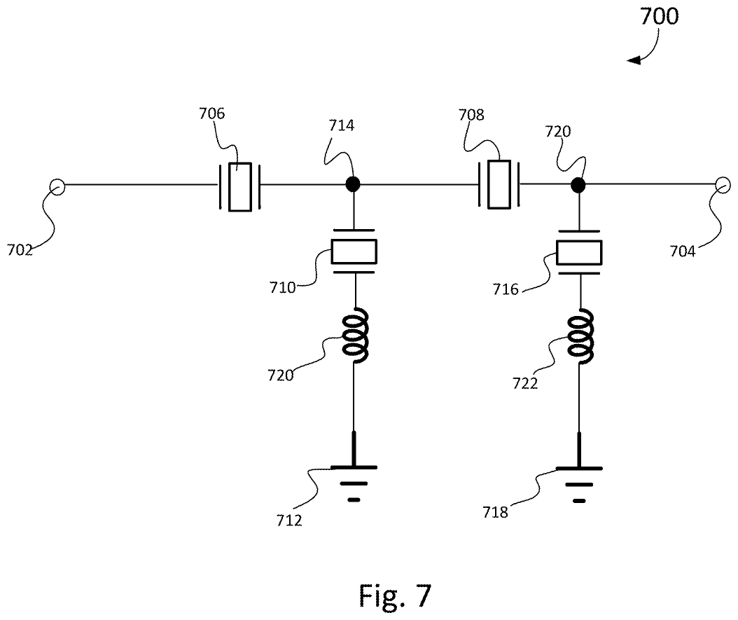

FIG. 7 is a schematic diagram illustrating an acoustic filter 700 according to embodiments of the subject technology. This diagram merely provides an example, which should not unduly limit the scope of the claims. One of ordinary skill in the art would recognize many variations, alternatives, and modifications. Acoustic filter 700 may include at least one of first port 702, second port 704, resonator 706, resonator 708, resonator 710, and resonator 716. For example, first port 702 and second port 704 may be configured to receive input or output signals (e.g., radio frequency signals). The ports can be adapted for various applications such as signal transmission or reception in communication devices.

In various implementations, resonator 706 may be associated with or operate at a first TE mode. The first TE mode may be greater than TE₁. Resonator 708 may be coupled to resonator 706 at node 714. Resonator 708 may be associated with the first TE mode. In other words, resonator 706 and resonator 708 may be associated with or operate at the same TE mode (e.g., the first TE mode). In some embodiments, resonator 706 and resonator 708 may be configured in series.

In various implementations, resonator 710 may be coupled to node 714 and a ground terminal 712. Resonator 710 may be associated with or operate at a second TE mode (e.g., TE₁, TE₂, TE₃, etc.). Depending on the implementation, the first TE mode and the second TE mode may be the same or different. According to some embodiments, acoustic filter 700 further includes resonator 716 coupled to resonator 708 and a ground terminal 718. For instance, resonator 716 may be coupled to resonator 708 through a node 720. In some embodiments, resonator 710 and resonator 716 may be configured in parallel. Resonator 716 may be associated with the second TE mode. In other words, resonator 710 and resonator 716 may be associated with or operate at the same TE mode (e.g., the second TE mode).

In various embodiments, one or more resonators of acoustic filter 700 may operate at a high TE mode (e.g., TE₂ or higher). However, one of the challenges of operating acoustic filters at high TE modes is the presence of lower-order TE modes (e.g., TE₁ mode, which may compromise the filter's performance by introducing undesirable signal interference and distortion. In various implementations, acoustic filter 700 may further include an inductor 720 coupled to resonator 710. Inductor 720 may be configured to adjust the resonant frequency of the capacitance of resonator (e.g., resonator 710) to suppress lower modes. For example, by adjusting the inductance value of inductor 720, the resonant frequency may be shifted to the frequency of the TE₁ mode. This may create a notch in the filter's frequency response at the TE₁ frequency, thereby effectively suppressing the unwanted TE₁ mode. In some cases, acoustic filter 700 further includes an inductor 722 coupled to resonator 722 and ground terminal 718. Similar to inductor 720, inductor 722 may be configured to adjust the resonant frequency of a resonator (e.g., resonator 716) to suppress TE₁ mode and TE₁ frequency.

While the above is a full description of the specific embodiments, various modifications, alternative constructions and equivalents may be used. Therefore, the above description and illustrations should not be taken as limiting the scope of the subject technology which is defined by the appended claims.

What is claimed is:

1. A device, comprising:
a first resonator comprising a first layer coupled to and positioned between a first electrode and a second electrode, the first layer comprising a first piezoelectric material, the first resonator being associated with a first thickness extension (TE) mode, the first TE mode comprises a TEₙ mode, wherein n is an integer greater than or equal to 2;
a second resonator coupled to the first resonator at a first node; and
a third resonator coupled to the first node and a first ground terminal, the third resonator comprising a second layer coupled to and positioned between a third electrode and a fourth electrode, the second layer comprising a second piezoelectric material, the second resonator further comprising a third layer coupled to the third electrode.

2. The device of claim 1, wherein the first TE mode is associated with a frequency of at least 6 GHz.

3. The device of claim 1, wherein the third layer comprises a mass load.

4. The device of claim 1, further comprising a filter coupled to the first resonator, the filter being configured to suppress a TE₁ frequency.

5. The device of claim 1, wherein the first electrode and the second electrode being characterized by a thickness difference of at least 30%.

6. The device of claim 1, wherein the third electrode and the fourth electrode are characterized by a thickness difference of at least 30%.

7. The device of claim 1, wherein the third electrode and the fourth electrode are characterized by a thickness difference of less than 10%.

8. The device of claim 1, wherein the first electrode and the second electrode are characterized by a thickness difference of at least 150%, the first TE mode comprising a TE₂ mode.

9. The device of claim 1, further comprising a fourth resonator coupled to the second resonator and a second ground terminal.

10. The device of claim 9, wherein the first resonator and the second resonator are associated with the first TE mode, and the third resonator and the fourth resonator are associated with a second TE mode, the second TE mode is different from the first TE mode.

11. The device of claim 10, wherein the second TE mode comprises a TE₁ mode.

12. The device of claim 1, further comprising a filter coupled to the first resonator, the filter being configured to suppress a TE₁ frequency.

13. The device of claim 12, wherein the filter comprises an inductor and a capacitor.

14. A device comprising:
a first resonator comprising a first layer coupled to and positioned between a first electrode and a second electrode, the first layer comprising a first piezoelectric material, the first resonator being associated with a first thickness extension (TE) mode;
a second resonator coupled to the first resonator at a first node, the second resonator being associated with the first TE mode;
a third resonator coupled to the first node and a first ground terminal, the third resonator being associated with a second TE mode; and
a first filter coupled to the first resonator.

15. The device of claim 14, wherein the first resonator and the third resonator are configured in parallel.

16. The device of claim 14, further comprising a second filter coupled to the second resonator.

17. The device of claim 14, wherein the first filter is configured to suppress a third TE mode associated with the first resonator.

18. A device comprising:
a first resonator comprising a first layer coupled to and positioned between a first electrode and a second electrode, the first layer comprising a first piezoelectric material, the first resonator being associated with a first thickness extension (TE) mode, the first TE mode being associated with a frequency of at least 5 GHz;
a second resonator coupled to the first resonator at a first node, the second resonator being associated with the first TE mode;
a third resonator coupled to the first node and a first ground terminal; and
a fourth resonator coupled to the second resonator and a second ground terminal.

19. The device of claim 18, wherein the first resonator and the second resonator are configured in series.

20. The device of claim 18, wherein the third resonator and the fourth resonator are associated with a second TE mode, the second TE mode being different from the first TE mode.
